(19) United States
(12) Patent Application Publication
(10) Pub. No.: US 2022/0164639 A1
(43) Pub. Date: May 26, 2022

(54) A SYSTEM FOR MAPPING A NEURAL NETWORK ARCHITECTURE ONTO A COMPUTING CORE AND A METHOD OF MAPPING A NEURAL NETWORK ARCHITECTURE ONTO A COMPUTING CORE

(71) Applicant: Agency for Science, Technology and Research, Singapore (SG)

(72) Inventors: Roshan GOPALAKRISHNAN, Singapore (SG); Yam Song CHUA, Singapore (SG)

(21) Appl. No.: 17/599,301

(22) PCT Filed: Mar. 27, 2020
(86) PCT No.: PCT/SG2020/050185

§ 371 Date: Sep. 28, 2021

(30) Foreign Application Priority Data
Mar. 28, 2019 (SG) 10201902803T

(51) Int. Cl. G06N 3/063; G06N 3/04

(52) U.S. Cl. CPC G06N 3/063; G06N 3/0481

(57) ABSTRACT

A system for mapping a neural network architecture onto a computing core and a method of mapping a neural network architecture onto a computing core may be provided, the system comprises a neural network module configured to provide a neural network; a data input module coupled to the neural network module, the neural network module configured to provide input data to the neural network; a layer selector module coupled to the neural network module, the layer selector module configured to select a layer of the neural network; a pipeline module coupled to the layer selection module, the pipeline module configured to perform at least one backward pipelining analysis from the selected layer of the layer selector module, the pipeline module being arranged to perform the at least one backward pipelining analysis towards an input layer of the neural network; a mapper module coupled to the pipeline module, the mapper module being arranged to receive activation information from the pipeline module, the activation information based on the at least one backward pipelining analysis; and wherein the mapper module is further arranged to map at least the selected layer of the neural network using the activation information to a computing core.

### TECHNICAL FIELD

The present disclosure relates broadly to a system for mapping a neural network architecture onto a computing core and to a method of mapping a neural network architecture onto a computing core.

### BACKGROUND

Neuromorphic computing typically relates to a variety of brain-inspired computers, devices, and/or models that attempt to emulate the neural structure and operations of a human brain. Progress in neural networks and deep learning technologies have resulted in research efforts to develop specialized hardware for neural network computations.

Recent advancements in deep learning architecture have moved towards an increment in the number of intermediate, e.g. convolutional, layers in neural networks for better accuracy (e.g. an increase in convolutional layers typically increases the number of convolution operations performed for more accurate predictions/results).

One typical approach to create a hardware encompassing deep learning architecture has been to map an entire deep learning architecture onto a computing or neuromorphic chip such that, after training, inference can be made at each time-step (e.g. to apply a trained neural network model to make predictions/infer a result from input data). However, it has been recognized by the inventors that this approach has a demand/requirement for a hardware e.g. neuromorphic chip/hardware with as many cores as possible to map the entire architecture onto the hardware.

Furthermore, conventionally, an approach to a mapping technique is by pipelining (e.g. creating an organized pipeline/chain of instructions for a processor to process in parallel) with neurons representing different feature maps at each layer organized into groups. However, it has been recognized by the inventors that this approach creates a necessity to train the network considering the grouped neurons within layers which may require a significant amount of time and resources. In other words, for a conventional approach, there is a recognition that groups of neurons are selected while creating a neural network and these neurons are trained separately. The neural network being created also has to fit a specific hardware.

In view of the above, there exists a need for a system for mapping a neural network architecture onto a computing core and a method of mapping a neural network architecture onto a computing core that seek to address at least one of the problems discussed above.

### SUMMARY

In accordance with an aspect of the present disclosure, there is provided a system for mapping a neural network architecture onto a computing core, the system comprising a neural network module configured to provide a neural network; a data input module coupled to the neural network module, the neural network module configured to provide input data to the neural network; a layer selector module coupled to the neural network module, the layer selector module configured to select a layer of the neural network; a pipeline module coupled to the layer selection module, the pipeline module configured to perform at least one backward pipelining analysis from the selected layer of the layer selector module, the pipeline module being arranged to perform the at least one backward pipelining analysis towards an input layer of the neural network; a mapper module coupled to the pipeline module, the mapper module being arranged to receive activation information from the pipeline module, the activation information based on the at least one backward pipelining analysis; and wherein the mapper module is further arranged to map at least the selected layer of the neural network using the activation information to a computing core.

The layer selection module may be configured to select the layer of the neural network between the input layer and an output layer of the neural network.

The pipeline module may be further configured to perform at least one forward pipelining analysis from the selected layer of the layer selector module, the pipeline module being arranged to perform the at least one forward pipelining analysis from the selected layer away from the input layer.

The pipeline module may be further configured to perform at least another backward pipelining analysis from another layer further from the input layer than the selected layer, the at least another backward pipelining analysis being from the another layer towards the selected layer and the input layer.

The activation information may comprise an identification of and a number of activations needed in each layer of the neural network for the generation of activations in an adjacent layer of the each layer, the each layer being analysed in the at least one backward pipelining analysis.

The mapper module may be further arranged to perform the mapping to the computing core based on a crossbar array of synapses, the crossbar array providing an interconnected relationship between axons and neurons with each synapse arranged for at least one mathematical operation.

The mapper module may be further arranged to perform the mapping to the computing core with the crossbar array of synapses, the mapping being based on a matrix method.

The matrix method may be selected from a group consisting of a block matrix, a Toeplitz matrix and a hybrid matrix of a block matrix and Toeplitz matrix.

The system may further comprise a first storage module, the first storage module may be configured to store the activation information relating to the selected layer, output information relating to the selected layer or both.

In accordance with another aspect of the present disclosure, there is provided a method of mapping a neural network architecture onto a computing core, the method comprising providing a neural network; providing input data to the neural network; selecting a layer of the neural network; performing at least one backward pipelining analysis from the selected layer towards an input layer of the neural network; determining activation information based on the at least one backward pipelining analysis; and mapping at least the selected layer of the neural network using the activation information to a computing core.

The step of selecting a layer of the neural network may comprise selecting the layer between the input layer and an output layer of the neural network.

The method may further comprise performing at least one forward pipelining analysis from the selected layer away from the input layer.

The method may further comprise performing at least another backward pipelining analysis from another layer further from the input layer than the selected layer, the at least another backward pipelining analysis being from the another layer towards the selected layer and the input layer.

The step of determining activation information based on the at least one backward pipelining analysis may comprise identifying activations and determining a number of activations needed in each layer of the neural network for the generation of activations in an adjacent layer of the each layer, the each layer being analysed in the at least one backward pipelining analysis.

The step of mapping at least the selected layer of the neural network with the activation information to a computing core may comprise performing the mapping based on a crossbar array of synapses, the crossbar array providing an interconnected relationship between axons and neurons with each synapse arranged for at least one mathematical operation.

The method may further comprise performing the mapping to the computing core based on a matrix method.

The method may further comprise selecting the matrix method from a group consisting of a block matrix, a Toeplitz matrix and a hybrid matrix of a block matrix and Toeplitz matrix.

The method may further comprise storing the activation information relating to the selected layer, or storing output information relating to the selected layer or storing both the activation information relating to the selected layer and output information relating to the selected layer.

### BRIEF DESCRIPTION OF THE DRAWINGS

Exemplary embodiments of the invention will be better understood and readily apparent to one of ordinary skill in the art from the following written description, by way of example only, and in conjunction with the drawings, in which:

FIG. 1 is a schematic block diagram illustrating a system for mapping a neural network architecture onto a computing core.

FIG. 2A is a schematic drawing illustrating a backward pipelining analysis process in an exemplary embodiment.

FIG. 2B is a schematic drawing illustrating identified activations of FIG. 2A.

FIG. 3 is a schematic drawing for illustrating exemplary convolution layer activations in an exemplary embodiment.

FIG. 4A is a schematic drawing for illustrating a backward-forward analysis of pipelined mapping (B/FAPM) process conducted on a convolutional neural network in an exemplary embodiment.

FIG. 4B is a schematic drawing for illustrating a backward-backward analysis of pipelined mapping (B/BAPM) process conducted on a convolutional neural network in an exemplary embodiment.

FIG. 5 is a schematic drawing illustrating a split pipelining process or a backward-backward analysis of pipelined mapping (B/BAPM) process in an exemplary embodiment.

FIG. 6 is a schematic drawing illustrating another split pipelining process or a backward-forward analysis of pipelined mapping (B/FAPM) process in an exemplary embodiment.

FIG. 7A shows schematically components of a convolution example for illustrating a mapping operation.

FIG. 7B is an exemplary mapping of the example of FIG. 7A using block matrix with a crossbar array of synapses.

FIG. 7C is an exemplary mapping of the example of FIG. 7A using toeplitz matrix with a crossbar array of synapses.

FIG. 7D is an exemplary mapping of the example of FIG. 7A using a hybrid toeplitz-block matrix with a crossbar array of synapses.

FIG. 7E is an exemplary mapping of the example of FIG. 7A using a hybrid block-toeplitz matrix with a crossbar array of synapses.

FIG. 8 is a schematic block diagram for illustrating possible inputs and outputs of a mapper module in an exemplary embodiment.

FIG. 9 is a schematic flowchart for illustrating a method of mapping a neural network architecture onto a computing core in an exemplary embodiment.

FIG. 10 is a schematic drawing of a computer system suitable for implementing an exemplary embodiment.

### DETAILED DESCRIPTION

Exemplary embodiments described herein may relate broadly to neuromorphic computing. An exemplary embodiment may provide or facilitate mapping of one or more deep neural network architectures onto hardware, such as neuromorphic hardware, with a crossbar array of synapses. An exemplary embodiment may provide or facilitate mapping of one or more neural network architectures, such as convolutional neural network (CNN) architectures, onto one or more computing cores such as one or more neuromorphic cores.

In one exemplary embodiment, a process of mapping a neural network architecture onto a computing core may be followed. In the exemplary embodiment, it is desired to map an entire neural network onto neuromorphic hardware. It is recognized by the inventors that if mapping of the entire neural network exceeds an available number of cores in a neuromorphic hardware, then it may be desirable to reduce the size of the neural network.

One approach, to reduce the neural network size but still being to encompass/fit the entire neural network, is proposed in the exemplary embodiment. The approach comprises segmenting the entire neural network from e.g. the end layer to the first layer (or referred to as a backward analysis).

In the exemplary embodiment, once the entire neural network is segmented, then the mapping of the segmented network becomes pipelined with respect to an input to the mapped network. Pipelined mapping may refer to the way the input is provided in a pipeline after mapping the segmented neural network. The segmentation of the neural network reduces size while mapping. The inventors recognize that a higher output latency is instead incurred due to pipelining.

In the exemplary embodiment, it is determined whether the backward analysis of pipelined mapping (or termed BAPM in the description herein) can fit the entire neural network onto the available neuromorphic hardware. It is appreciated that if the backward analysis or the BAPM can fit the entire neural network onto the available neuromorphic hardware, then the BAPM is sufficient.

If the BAPM is still not able to fit the entire neural network onto the hardware, then it is desired to further reduce the network size to be able to perform the mapping. In the exemplary embodiment, the further reduction is by exploring the backward analysis from an intermediate layer instead of the end layer (for example, the backward analysis is performed from mid layer). It is recognized that it is possible to perform the backward analysis from any other suitable intermediate layer within the neural network. The selection of the intermediate layer may be arbitrary or may be via an algorithm considering the constraints of the hardware.

In the exemplary embodiment, to perform the backward analysis of pipelined mapping from an intermediate layer, a form of split pipelined mapping is adopted as the BAPM is split into either a backward-backward analysis of pipelined mapping (or termed B/BAPM in the description herein) or a backward-forward analysis of pipelined mapping (or termed B/FAPM in the description herein). Further examples of such split pipelined mapping are provided in exemplary embodiments described hereinafter.

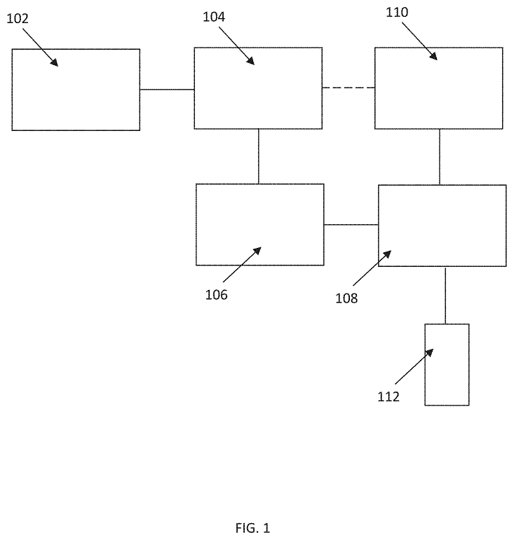

FIG. 1 is a schematic block diagram illustrating a system for mapping a neural network architecture onto a computing core. The system 100 comprises a data input module 102 coupled to a neural network module 104. The neural network module 104 is coupled to a layer selector module 106 that is in turn coupled to a pipeline module 108. The pipeline module 108 is coupled to a mapper module 110. In some exemplary embodiments, the components of the system 100 may be coupled to a processing module (not shown) that may instruct and control the operations of the system 100.

In the exemplary embodiment, the data input module 102 is arranged to provide input data to a neural network. Such input data may comprise, but is not limited to, an input image. The neural network module 104 is arranged to provide at least one neural network, such as e.g. a convolutional neural network (CNN). For example, the CNN is a trained CNN.

In the exemplary embodiment, the layer selector module 106 is arranged to select a layer of a neural network provided at the neural network module 104. The layer may be a predetermined layer. The layer may be selected via a user input. The selected layer may be a mid layer of the neural network or an end layer of the neural network. It is recognized that the selected layer may also be any intermediate layer of the neural network. Information regarding the selected layer is transmitted to the pipeline module 108. The pipeline module 108 is arranged to conduct at least one backward pipelining analysis, or backward analysis of pipelined mapping, from the selected layer towards an input layer containing the input data. Information regarding and based on the at least one backward pipelining analysis is transmitted to the mapper module 110. The information comprises activation information such as a number of activations for each layer in relation to another layer e.g. an adjacent layer. The mapper module 110 is arranged to map at least the selected layer of the neural network using the activation information to a computing core.

In some exemplary embodiments, the mapping is conducted to map the layers analysed during the at least one backward pipelining analysis with the activation information onto the computing core, such as a neuromorphic core. In some exemplary embodiments, the mapper module 110 may access the neural network of the neural network module 104 (compare dotted connection). It is appreciated that if the neural network cannot be mapped onto a single computing core (using the BAPM), then a section of the neural network is mapped onto a respective core. The pipelined mapping allows for the mapping of the entire neural network onto a plurality of such cores (e.g. using split pipelined mapping such as the B/BAPM or B/FAPM).

In some exemplary embodiments, the activation information may further comprise an identification of activations that are needed/required in each layer for the generation of activations in another layer e.g. an adjacent layer. In some exemplary embodiments, the mapper module 110 is arranged to determine a number of cores of a computing hardware to map e.g. each layer with a needed/required number of neurons in each layer for the generation of activations in another layer e.g. an adjacent layer. In some exemplary embodiments, at each time step, the pipeline module 108 is arranged to conduct a backward pipelining analysis that corresponds to a partition/portion of the input layer (or input data).

In the exemplary embodiment, the system 100 may further comprise a first storage module 112 coupled to the pipeline module 108. The first storage module 112 may be configured to store the activation information relating to the selected layer. For example, the first storage module 112 may store in a buffer the determined number of activations for the selected layer such that another backward analysis or forward analysis may be conducted or performed towards or from the selected layer respectively.

In the exemplary embodiment, at least one backward pipelining analysis from the selected layer towards an input layer containing the input data is conducted. For example, if it is desired to find/locate a single activation in the selected layer ‘No’ of a deep neural network architecture such as the neural network provided at the neural network module 104, with the available kernel size and stride for that particular layer ‘N₀’, the pipeline module 108 is arranged to identify the activations in a previous layer ‘N₀−1’ to generate the single activation in the present selected layer ‘N₀’. The previous layer ‘N₀−1’ is analysed towards and closer to the input layer of the neural network as compared to ‘N₀’. Following the analysis of layer ‘N₀−1’, the pipeline module 108 is arranged to identify the activations in yet another previous layer ‘N₀−2’ to generate those identified activations in layer ‘N₀−1’. The layer ‘N₀−2’ is analysed towards and closer to the input layer of the neural network as compared to ‘N₀−1’ and ‘N₀’. The iteration of the backward analysis continues backwards up to the input image or input layer.

The inventors recognize that a backward pipelining analysis as described above effectively partitions an input image for pipelining e.g. processing a partition at each time-step. Such an approach may usefully reduce the number of computing or neuromorphic cores otherwise needed to map an entire deep neural network architecture.

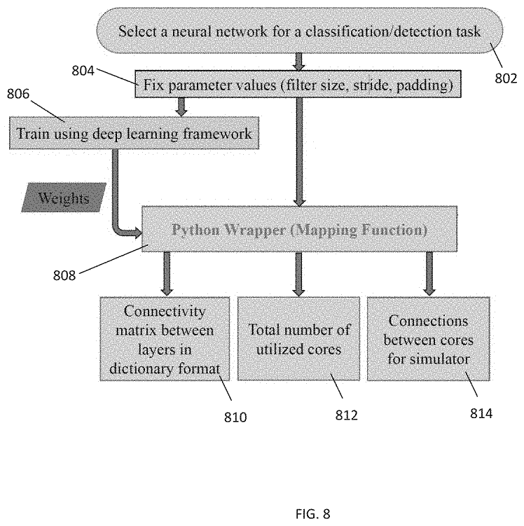

FIG. 8 is a schematic block diagram for illustrating possible inputs and outputs of a mapper module in an exemplary embodiment. At block 802, a neural network is selected and provided for a classification or detection task. The neural network may be provided at a neural network module (compare e.g. neural network module 104 of FIG. 1). At block 804, parameter values may be provided for the selected neural network. For example, parameters relating to filter size, stride, padding etc. may be provided. Such parameter values may be provided at an input module (compare e.g. data input module 102 of FIG. 1). The parameter values are also made available and input to a mapper module (compare e.g. mapper module 110 of FIG. 1). At block 806, the selected neural network is trained and the weights are determined via the training process. The trained neural network and weights information are provided and input to the mapper module. At block 808, the mapper module is configured to map the trained neural network to neuromorphic hardware, e.g. one or more neuromorphic cores. At block 808, backward analysis of pipelined mapping (BAPM) may be performed. In addition or as an alternative, e.g. depending on the size of the trained neural network and available neuromorphic hardware, a backward-backward analysis of pipelined mapping (B/BAPM) or a backward-forward analysis of pipelined mapping (B/FAPM) may be performed.

In the exemplary embodiment, the mapper module may provide/output one or more output information. At block 810, the mapper module may provide a connectivity matrix as information between layers of the neural network and in a dictionary format, e.g. for lookup purposes. At block 812, the mapper module may provide information relating to the total number of neuromorphic core(s) utilized for mapping the trained neural network onto a neuromorphic chip. In one example, if the neural network may be mapped onto a single neuromorphic chip, then only one chip is utilized. Otherwise, two or more chips may be utilized for two or more sections of the neural network. At block 814, if more than one core has been utilized in a neuromorphic chip, the mapper module may provide information relating to connections between neuromorphic cores in a neuromorphic chip, e.g. as an user interface for the neuromorphic chip simulator.

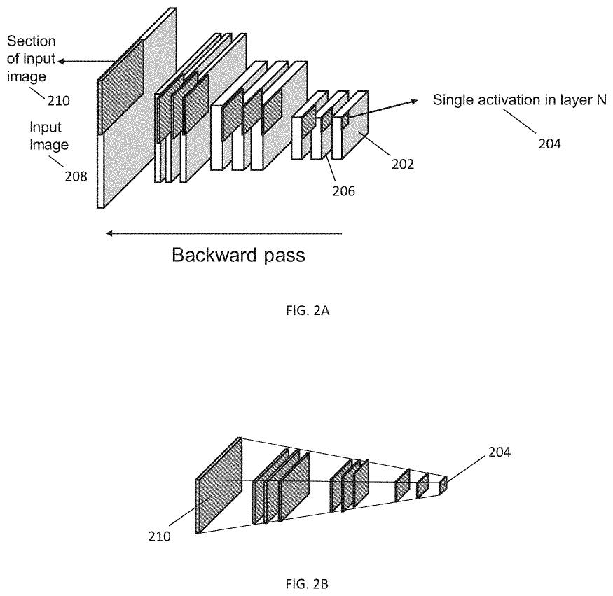

FIG. 2A is a schematic drawing illustrating a backward pipelining analysis process in an exemplary embodiment. A layer N 202 is selected and a single activation 204 is located in the layer N 202. In the analysis process, activations in a previous layer 206 are identified, these activations being able to generate the activation 204 of the layer N 202. The previous layer 206 is analysed towards and closer to an input image 208 as compared to the layer N 202. The iteration of the backward analysis continues backwards up to the input image 208. It is observed that the backward pipelining analysis process effectively partitions the input image 208 such that a section 210 of the input image 208 is at an end of the pipeline or channel.

FIG. 2B is a schematic drawing illustrating the identified activations of FIG. 2A. It is shown that the pipeline or channel has the section 210 of the input image 208 at one end and the activation 204 of the layer N 202 at another end.

In the above exemplary embodiment, both the number (or size) and identities of the activations may be determined. A mapping may therefore take into account the number (or size) for determination of a number of cores that may be utilized for mapping and the activations for mapping to the neurons of each next forward layer.

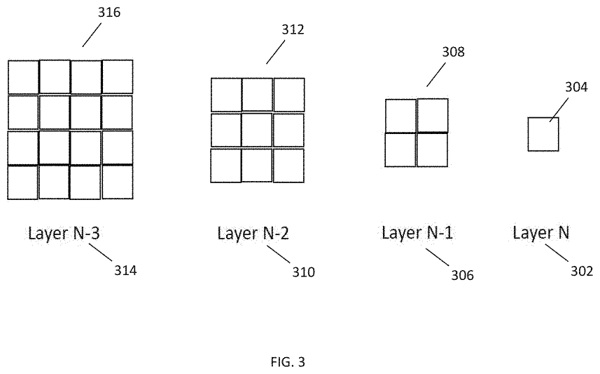

FIG. 3 is a schematic drawing for illustrating exemplary convolution layer activations in an exemplary embodiment. There is shown a selected layer N with a single (1) activation 304. In the exemplary embodiment, the convolution layer activations are conducted with a convolution kernel/filter of 2×2 and stride of 1. In FIG. 3, the number of square boxes in each layer represents the number of activations desired to generate activation(s) in previous layers using the filter of 2×2 and stride of 1. For example, for the layer N 302 with the activation 304, which is a previous layer to the layer N−1 306, the layer N−1 306 requires 2×2=4 activations to generate the single (1) activation in the layer N 302. The four activations 308 of layer N−1 306 are shown. The layer N−2 310 requires (3×3=9) nine activations 312 to generate the four activations 308 in the layer N−1 306. The layer N−3 314 requires (4×4=16) sixteen activations 316 to generate the nine activations 312 in the layer N−2 310. This backward analysis may be performed until an input layer. For the ease of illustration, only four layers are illustrated in FIG. 3.

In another exemplary embodiment, with an at least one backward pipelining analysis, further analysis steps or processes may also be undertaken e.g. by a pipeline module (compare pipeline module 108 of FIG. 1). For example, the pipeline module may conduct another backward pipelining analysis from another layer such as an end layer backwards towards a selected layer ‘N₀’.

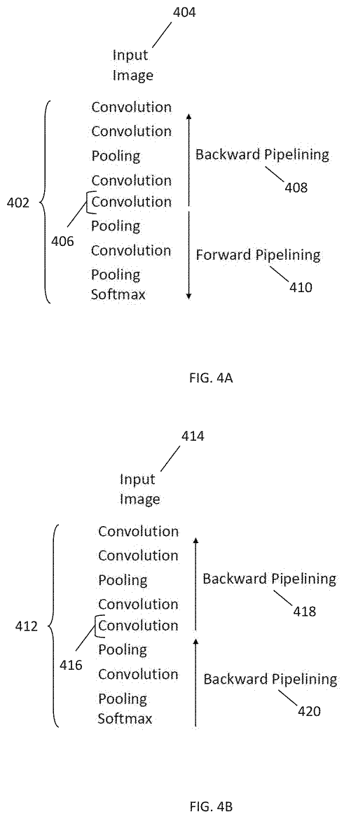

FIG. 4A is a schematic drawing for illustrating a backward-forward analysis of pipelined mapping (B/FAPM) process conducted on a convolutional neural network in an exemplary embodiment. The backward-forward process may also be termed as backward-forward analysis of pipelined mapping (B/FAPM). The convolutional neural network 402 may receive an input image 404 as input data. An intermediate layer 406 is selected for a backward pipelining process 408 to be conducted towards an input layer for containing input data. A forward pipelining process may be conducted from the intermediate layer 406 towards an end layer.

FIG. 4B is a schematic drawing for illustrating a backward-backward analysis of pipelined mapping (B/BAPM) process conducted on a convolutional neural network in an exemplary embodiment. The backward-backward process may also be termed as backward-backward analysis of pipelined mapping (B/BAPM). The convolutional neural network 412 may receive an input image 414 as input data. An intermediate layer 416 is selected for a backward pipelining process 418 to be conducted towards an input layer for containing input data. Another backward pipelining process 420 may be conducted from an end layer towards the intermediate layer 406.

The concept illustrated in FIGS. 4A and 4B may be termed split pipelining. The concept may encompass starting a process of pipelining with backward analysis at an intermediate layer of a neural network rather than from a last layer at the output of the network. Split pipelined mapping may be used if an entire neural network may not be mapped onto a single computing core. In exemplary embodiments, a selected layer N or N₀ may be an intermediate layer of a neural network, e.g. a CNN.

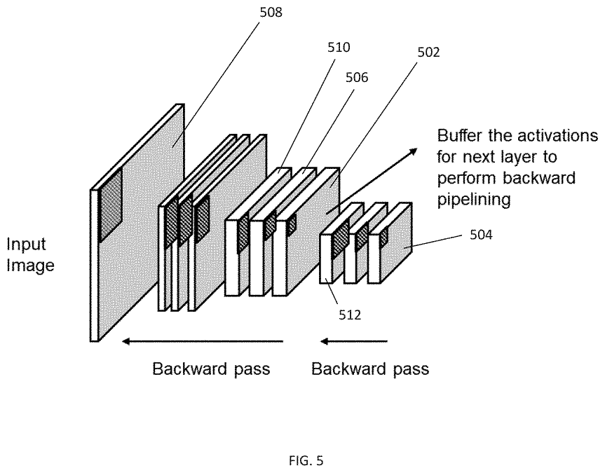

FIG. 5 is a schematic drawing illustrating a split pipelining process or a backward-backward analysis of pipelined mapping (B/BAPM) process in an exemplary embodiment. The process may be performed e.g. by a system substantially similar to the system 100 of FIG. 1.

In the exemplary embodiment, a backward analysis is performed at an intermediate layer towards an input image while another backward analysis is performed from an end layer towards the intermediate layer. Compare e.g. the B/BAPM of other exemplary embodiments.

In the exemplary embodiment, an intermediate layer 502 is selected or chosen to perform a backward analysis or backward pipelining analysis as described in other exemplary embodiments. The intermediate layer 502 may be a mid layer of a neural network. The intermediate layer 502 may also be any other intermediate layer of the neural network. In the exemplary embodiment, an end layer 504 is also selected to perform a backward analysis or backward pipelining analysis as described in other exemplary embodiments.

For the intermediate layer 502, the backward pipelining analysis is performed to identify the activations and determine or find the number of activations (or output of neurons) needed in each layer for the generation of activations in the next layer (the each layer being backwards towards e.g. an input layer). For example, if the intermediate layer 502 is layer N, then it is to be determined the number of activations in a layer N−1 or a layer 506, that is closer to an input image data 508 than the intermediate layer 502, that generate the activations in the intermediate layer 502. Similarly, it is to be determined the number of activations in another layer N−2 or a layer 510, that is closer to an input image data 508 than the layer 506, that generate the activations in the layer 506.

For the end layer 504, similarly, another backward pipelining analysis is also performed towards the selected intermediate layer 502 to identify the activations and determine or find the number of activations. In the exemplary embodiment, the first backward pipelining analysis for the intermediate layer 502 is completed prior to said another backward pipelining analysis from the end layer 504 such that the number of activations for the layer 502 are determined and stored in a buffer. For example, with the determined number of activations determined for the layer 502, backward analysis may be performed e.g. from a next layer 512. For example, compare the first storage module 112 of FIG. 1.

Thus, in the exemplary embodiment, backward analysis is performed from the selected intermediate layer 502 to the layer 508, as well as from the end layer 504 to the next layer 512 (of the intermediate layer 502). The first backward analysis from the intermediate layer 502 to the layer 508 is stored in a buffer to wait for a number of time steps (i.e. the time steps depend on the input activations needed in the layer 512 for the second backward analysis to be performed) before the second backward analysis may be performed from the end layer 504 to the next layer 512. Hence, a buffer storage is used at the intermediate layer 502 or between the two backward analysis.

In the exemplary embodiment, the below equation may be used to find the number of activations:

Output size=(Input size−kernel size+2*padding)/stride+1 (1)

In the exemplary embodiment, to find the number of activations needed for each layer, the backward pipeline analysis is performed for all neurons starting from the intermediate layer 502. The backward analysis is performed similarly from the end layer 504 to the intermediate layer 502. Equation (1) allows for the determination of the number of activations (i.e. input size in the equation) needed in each layer, e.g. from the end layer 504 to the first or input layer 508, with respect to the output size in the equation. The output size of the end layer 504 is considered to be 1 (one). The equation may be used in both the backward pipelining sections of the B/BAPM.

In the exemplary embodiment, after determining the number of activations needed in each layer for the generation of activations in the next layer (the each layer being backwards towards e.g. an input layer), a number of cores is determined for mapping each layer with the determined/required number of activations/neurons. For example, the selected neurons in the layers 502 to 508 may be mapped to the neurons in a neuromorphic chip.

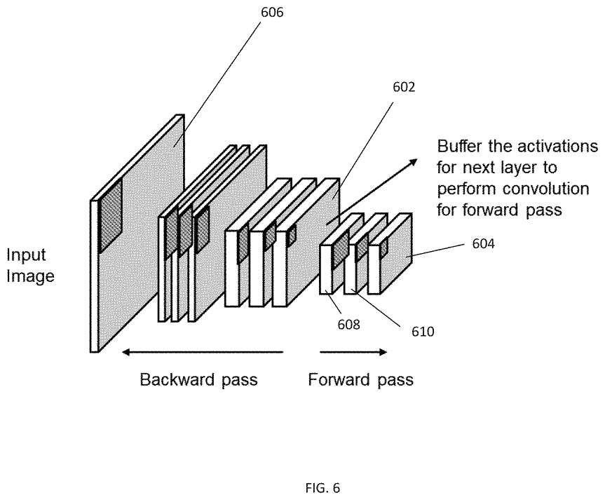

FIG. 6 is a schematic drawing illustrating another split pipelining process or a backward-forward analysis of pipelined mapping (B/FAPM) process in an exemplary embodiment. The process may be performed e.g. by a system substantially similar to the system 100 of FIG. 1.

In the exemplary embodiment, a forward analysis of pipelined mapping is performed. When the activations become available for the forward layer(s) of a neural network (i.e. layers closer to the end layer of the neural network as compared to an intermediate layer selected for performing a backward analysis of pipelined mapping), these available activations may be stored in a buffer. The activations needed for these forward layer(s) are then determined using Equation (1). The output size may be calculated depending on the available input size (i.e. provided by each layer closer to the input layer as the forward analysis is performed).

In the exemplary embodiment, a backward analysis is performed at an intermediate layer towards an input image while a forward analysis is performed from the intermediate layer towards an end layer. Compare e.g. the B/FAPM of other exemplary embodiments.

In the exemplary embodiment, an intermediate layer 602 is selected or chosen to perform a backward analysis or backward pipelining analysis as described in other exemplary embodiments. For example, the backward analysis described in relation to layers 502, 506, 508, 510 of FIG. 5 to identify activations and to determine the number of activations needed in each layer for the generation of activations in the next layer (the each layer being backwards towards e.g. an input layer) is also performed for the intermediate layer 602 towards an input image data 606. In the exemplary embodiment, the intermediate layer 602 may be a mid layer of a neural network. The intermediate layer 602 may also be any other intermediate layer of the neural network.

In the exemplary embodiment, a forward analysis is performed from the intermediate layer 602 towards an end layer 604. The outputs from the intermediate layer 602 (for a current input image data 606) are stored in a buffer until these outputs may be used for processing the next immediate output in a next layer 608, e.g. the outputs may be used for the next layer 608 to perform convolution calculations. For example, the neurons in the intermediate layer 602 may be buffered, such that the neurons in the layer 608 may get activated. Further, these buffered neurons are used in the forward analysis of pipelined mapping. For example, compare the first storage module 112 of FIG. 1. Thus, in the exemplary embodiment, for the forward analysis, in between each layer in the neural network, a buffer storage is utilised for the forward pipelining.

It is recalled that each backward pipelining analysis process may effectively partition the input image data. In the exemplary embodiment, after all partitions of the current input image are processed, the backward pipelining analysis and forward analysis may be applied to a first partition of a next input image data. The inventors have recognised that such a split pipelining approach, e.g. illustrated with FIG. 6, may incur inference latency on one hand but significantly reduce number of cores used for mapping the neural network.

In the exemplary embodiment, the buffering process to store outputs of each layer for the forward analysis (from the intermediate layer 602) is iteratively performed for the layer 608 and for the next layers e.g. 610 towards the end layer 604, in order to determine the number of activations needed in each layer for the generation of activations in the next layer towards the end layer 604.

For the exemplary embodiment, it is recognised by the inventors that the buffering process for FIG. 6 is different from the buffering process described with reference to FIG. 5.

After determining the number of activations needed in each layer for the generation of activations in the next layer (towards the end layer 604), a number of cores is determined for mapping each layer with the determined/required number of activations/neurons. For example, the selected neurons in the layers 602 to 606 may be mapped to the neurons in a neuromorphic chip.

With some exemplary embodiments, the inventors have recognised that there may be a constraint for determining intermediate layers, considering axons available for a (one) computing core or neuromorphic core.

The inventors have recognised that the determination of an intermediate layer to be selected for the backward analysis may depend on several factors such as, for example, the number of network layers, the size of the input dataset, output latency etc. The inventors recognise that it is possible to segment the input layer into ‘N’ divisions, that for ‘N’ segments, it may be determined the number of input activations in the input layer and thus, the intermediate layer may be calculated or identified using Equation (1) such that the input size becomes 1 in Equation (1) so that the backward analysis from the intermediate layer towards the input layer may be performed.

Using Equation (2) below, which is also shown at Equation (1):

$$Output size = \frac{( Input size - kernal size + 2 * padding )}{Stride} + 1 \qquad ( 2 )$$

The input size or activation size can be calculated throughout a backward pass from an intermediate layer N to layer 1 or input layer.

The above Equation (2) can be rewritten as below:

Aₗ₋₁=(Aₗ−1)*Sₗ+Kₗ ∀l∈end layer to first layer (3)

A=Activation size
K=Kernel size

### S=Stride

The inventors have recognised that padding may be excluded in the above Equation (3) to calculate the activations in a previous layer as it is recognised to be inherently included in the activation size calculations.

The above Equation (3) is iterated for a different number of layers, l until a correct input section is determined with the following condition such that

Aₗ₋₁*Aₗ₋₁<=number of axons/input channel size; where l−1 denotes the activation size of the input image.

As such, it may be determined that the larger the number of axons available for a core, the more neurons (in relation to layers) that may be mapped onto the core.

The exemplary embodiments, described e.g. with reference to FIGS. 2A, 4A, 4B, 5 and 6, illustrate a concept of pipelining with backward analysis among different layers of a neural network, e.g. a CNN. Compare e.g. FIGS. 4A and 4B. Backward pipelining is performed from a mid-layer whereas the rest of the convolutional layers may carry on with forward pipelining or backward pipelining. The combined backward and forward pipelining technique or backward and backward pipelining technique is termed as split pipelining. Compare FIGS. 2A, 5 and 6.

In the exemplary embodiments described, for example, with reference to FIGS. 1, 5 and 6, mapping may be performed by a mapper module (compare e.g. the mapper module 110 of FIG. 1).

In exemplary embodiments, mapping may be based on a crossbar architecture of synapses in a computing core, e.g. a neuromorphic chip/core. For a biological neuron, an axon connects the pre-synaptic neuron to the synapse, which is the site of connection between the axon of the pre-synaptic neuron and the dendrite of the post-synaptic neuron. The axon can conduct electrical impulses from the neuron's cell body. Similarly, in neural networks such as CNNs on a neuromorphic hardware, the synapse can be viewed as the site of connections between the input neurons and output neurons of a convolution layer. The inventors recognise that a memory device may be used to represent these synaptic weights which are analogous to the weights in the filters of the CNNs. In the mesh-like crossbar array, the synapse of the neuromorphic core establishes connections between axons and neurons of that neuromorphic core. It is recognised that in a neuromorphic chip, spiking neurons are used to integrate the current from the synapses and a spike is emitted, when the firing threshold is met. Hence, each neuron at the bottom of the crossbar array may perform a nonlinear function on the convolution operation between input and synaptic weights. These operations are also termed as matrix dot vector multiplications.

The inventors have recognised that, in exemplary embodiments, given a CNN chosen for a classification or detection task, its hyper-parameters such as filter size, strides and padding at each layer are known. It is therefore possible to determine the number of activations for each layer and map such information onto a neuromorphic core/chip. There may be number of axons and neurons utilized in a single neuromorphic core, represented as [axons×neurons]. It is possible to calculate the number of axons and the number of neurons used for mapping a section of a particular layer onto a single core. For a given mapping on a particular core, a core utilization may be calculated based on the number of neurons and axons connected together.

For a crossbar array of synapses, the inventors have recognised that, mathematically, convolution is the sum of dot product of two input matrices. One matrix may be the input matrix and the other matrix may be the filter matrix. In CNNs, the input matrix is the activations from the prior layer while the filter matrix is the convolution filter kernel, saved as weights, W after a CNN is trained. Thus, using a crossbar array of synapses, a single column of a crossbar may give the output of a convolution operation, which is the output of a corresponding neuron.

In exemplary embodiments, the inventors have recognised that three exemplary methods/processes/algorithms may be used for optimized core utilization to map neural network architectures on to a neuromorphic core with a crossbar array of synapses, depending on the convolutional layers involved (depthwise convolution, pointwise convolution, etc.). The three exemplary methods/processes/algorithms are usage of a block matrix, or a toeplitz matrix and/or a hybrid (block-toeplitz or Toeplitz-block) matrix. With these exemplary methods/processes/algorithms, it is possible to map neural network architecture/algorithms onto a neuromorphic core with a crossbar array of synapses.

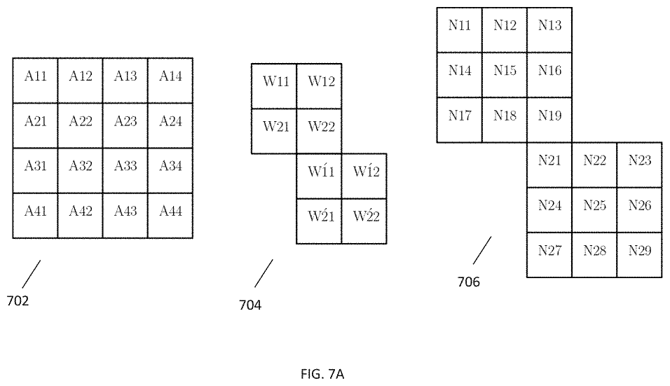

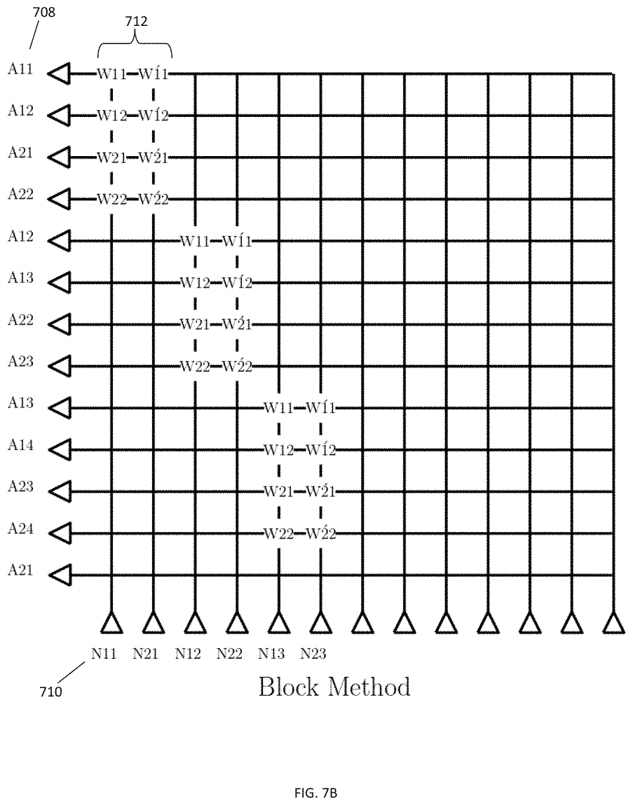

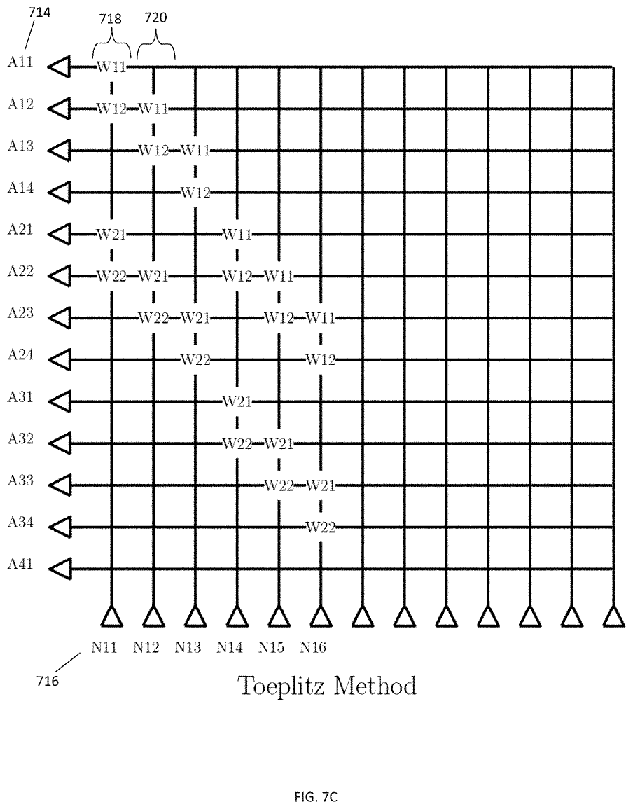

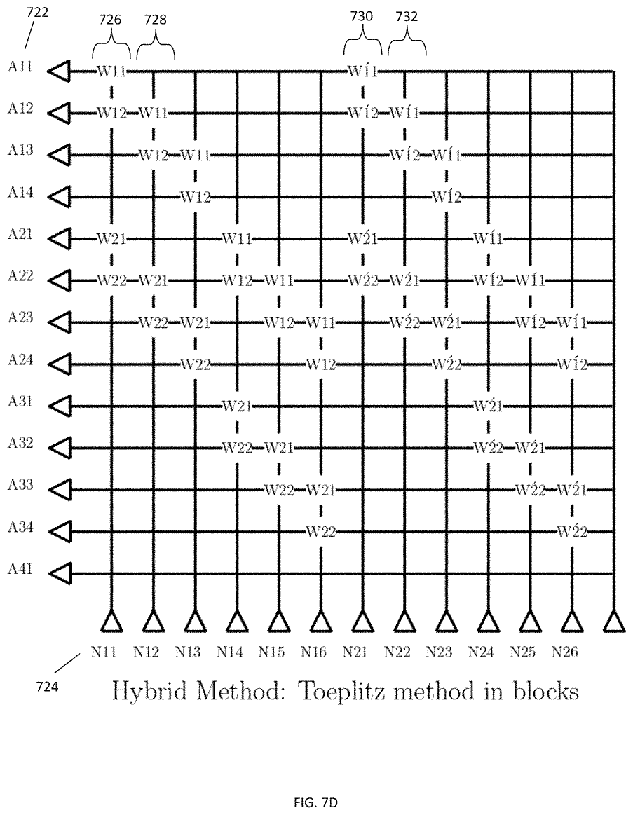

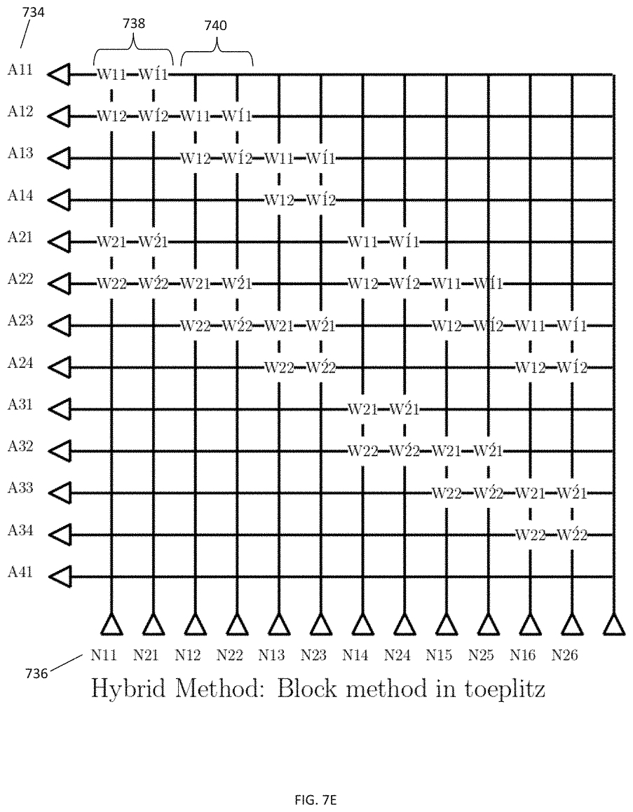

FIG. 7A shows schematically components of a convolution example for illustrating a mapping operation. An input layer 702 of size 4×4 and a set of filter weights 704 of size 2×2×2 are provided for convolution to obtain an output layer 706. Compare, for example only, layer 510 of FIG. 5 as an input layer and layer 506 of FIG. 5 as an output layer.

In this example, the inputs of layer 702 are denoted by A with numerals for row by column. The weights 704 are schematically denoted by W with numerals for row by column, with a set of weights additionally denoted by a diacritic acute sign with the numerals. The outputs of layer 706 are denoted by N from N11 to N19 and from N21 to N29.

FIG. 7B is an exemplary mapping of the example of FIG. 7A using block matrix with a crossbar array of synapses. FIG. 7C is an exemplary mapping of the example of FIG. 7A using toeplitz matrix with a crossbar array of synapses. FIG. 7D is an exemplary mapping of the example of FIG. 7A using a hybrid toeplitz-block matrix with a crossbar array of synapses. FIG. 7E is an exemplary mapping of the example of FIG. 7A using a hybrid block-toeplitz matrix with a crossbar array of synapses.

In these examples, the horizontal lines represent input axons while the vertical lines connect the input axons to output neurons that are represented at the base of each example. The weighted notations shown at intersections of these horizontal and vertical lines are weighted synapses. Intersections without these nodes represent synapses with zero weights. In these examples, the constraint of each core is shown at 13×13 input-output.

In the described exemplary embodiments, with the identification of activations needed and determination of a required number of neurons needed in a layer required to generate activations in a next layer, and with the determination of a number of cores needed to map each layer with the required number of neurons needed, mapping may be performed for each core.

At FIG. 7B, using a block matrix method, the input axons shown vertically at numeral 708 are observed to be laid out in block form at 2×2 with stride 1. The output neurons are shown at the base of the example at numeral 710. The weighted synapses are shown e.g. at numeral 712. In this example, while all eight weights (including those with the diacritic acute sign) may be represented for each operation, only six outputs may be shown with the thirteen input axons and that may be mapped using a single core.

At FIG. 7C, using a toeplitz matrix method, the input axons shown vertically at numeral 714 are observed to be laid out based on a sequential listing horizontally of each line of the input layer 702. The output neurons are shown at the base of the example at numeral 716. The weighted synapses are shown e.g. at numeral 718 and vertically down from numeral 720. In this example, it is observed that only four of the eight weights (i.e. excluding those with the diacritic acute sign) are represented for each operation. In this example, only six outputs may be shown with the thirteen input axons and that may be mapped using a single core.

To be able to map more outputs to the thirteen input axons, hybrids of the block and Toeplitz methods are considered.

At FIG. 7D, using a Toeplitz method in block hybrid, the input axons shown vertically at numeral 722 are observed to be laid out based on a sequential listing horizontally of each line of the input layer 702. Compare also numeral 714 of FIG. 7C. The output neurons are shown at the base of the example at numeral 724. The weighted synapses are shown e.g. at numeral 726, numeral 730, and vertically down from numeral 728 and numeral 732. In this example, it is observed that all eight weights (including those with the diacritic acute sign, see e.g. vertically down from numerals 730 and 732) are represented for each operation. In this example, twelve outputs may be shown with the thirteen input axons and that may be mapped using a single core.

At FIG. 7E, using a block method in toeplitz hybrid, the input axons shown vertically at numeral 734 are observed to be laid out based on a sequential listing horizontally of each line of the input layer 702. Compare also numeral 714 of FIG. 7C and numeral 722 of FIG. 7D. The output neurons are shown at the base of the example at numeral 736. The weighted synapses are shown e.g. vertically down from numeral 738 and vertically down from numeral 740. In this example, it is observed that all eight weights (including those with the diacritic acute sign, see e.g. vertically down from numerals 738 and 740) are represented for each operation. In addition, it is observed that the weights are represented in block form, see e.g. vertically down from numerals 738 and 740. In this example, twelve outputs may be shown with the thirteen input axons and that may be mapped using a single core.

As such, as may be observed from FIGS. 7D and 7E, more outputs may be mapped using a hybrid method, given a maximum constraint on the input axons, as compared to using a block matrix or a Toeplitz matrix method.

Using the examples shown in FIGS. 7B to 7E, e.g. the Toeplitz and hybrid methods of mapping, a mapping of a section of a neural network (such as a CNN) may be performed onto a single neuromorphic chip. In some exemplary embodiments, if an entire neural network may be mapped onto a single neuromorphic chip, then backward analysis from the end layer towards the input layer is sufficient for mapping to be performed. In other exemplary embodiments, if an entire neural network cannot be mapped onto a single neuromorphic chip, split pipelined mapping may be performed to map different sections of an entire neural network respectively onto a plurality of neuromorphic cores, i.e. with the individual core mapping performed using, for example, one of the examples shown in FIGS. 7B to 7E.

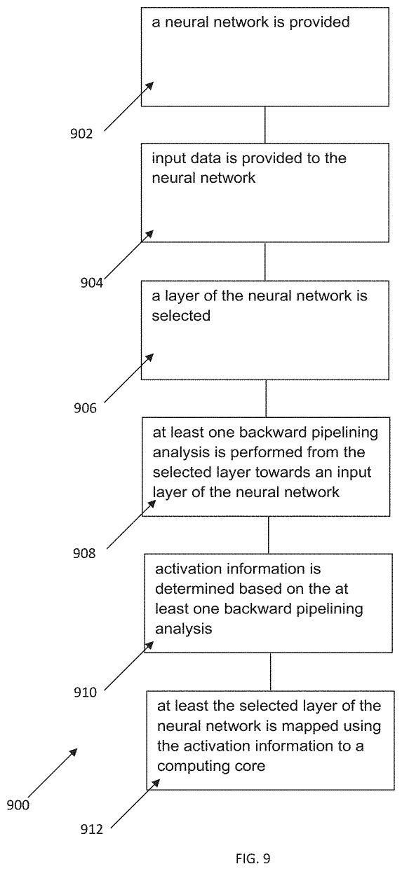

FIG. 9 is a schematic flowchart 900 for illustrating a method of mapping a neural network architecture onto a computing core in an exemplary embodiment. At step 902, a neural network is provided. At step 904, input data is provided to the neural network. At step 906, a layer of the neural network is selected. At step 908, at least one backward pipelining analysis is performed from the selected layer towards an input layer of the neural network. At step 910, activation information is determined based on the at least one backward pipelining analysis. At step 912, at least the selected layer of the neural network is mapped using the activation information to a computing core.

The above method may be a computer implemented method. That is, there may be provided a non-transitory tangible computer readable storage medium having stored thereon software instructions that, when executed by a computer processor of a system for mapping a neural network architecture onto a computing core, cause the computer processor to perform a method of mapping a neural network architecture onto a computing core, by executing the steps comprising, providing a neural network; providing input data to the neural network; selecting a layer of the neural network; performing at least one backward pipelining analysis from the selected layer towards an input layer of the neural network; determining activation information based on the at least one backward pipelining analysis; and mapping at least the selected layer of the neural network with the activation information to a computing core.

With the described exemplary embodiments, the inventors recognise that careful architectural design with both the knowledge of neuromorphic hardware, and its limitations, along with deep learning algorithms may provide for an efficient design of neuromorphic hardware.

The described exemplary embodiments may usefully reduce the utilization of a significant number of neuromorphic cores while mapping deep neural network architectures onto a neuromorphic chip with a synaptic crossbar array.

In one exemplary embodiment, a CNN is pipelined from mid-layer, so as to drastically/significantly reduce a number of cores by at least an order of magnitude. By processing only a portion of an image in each time-step, in a way, pipelining is performed by partitioning the input image, which effectively reduces the number of cores needed for inference. This approach further reduces the number of neuromorphic cores needed to map an entire deep learning architecture compared to pipelining from a final layer. The inventors recognise that some exemplary embodiments may use intermediate activation buffers.

With the described exemplary embodiments, an entire neural network may be mapped onto neuromorphic hardware. A neural network may be segmented using a backward analysis of pipelined mapping (BAPM) from an end layer of the neural network to a first layer of the neural network. The mapping of that segmented network thus becomes pipelined with respect to the input to the mapped network. If the BAPM is not sufficient to fit the entire neural network to an available number of core(s), with one or more described exemplary embodiments, the network size may be further reduced to map by exploring the backward analysis from an intermediate layer of the neural network. In such exemplary embodiments, the backward analysis of pipelined mapping from the intermediate layer may become split pipelined mapping as the BAPM is split into either a backward-backward analysis of pipelined mapping (B/BAPM) or a backward-forward analysis of pipelined mapping (B/FAPM).

In one exemplary embodiment, a pipelined mapping of deep neural network architectures onto a neuromorphic chip with a plurality of interconnected neuromorphic cores comprising interconnected arrays of axons and neurons is provided, with each interconnection being a synapse which may perform both multiplication (e.g. of weight and input) and storage while a neuron may generate spikes when integration of weighted inputs exceeds a threshold.

The pipelining may be performed in a backward analysis approach considering only a subset of the entire architecture in order not to include the entire deep learning architecture during pipelining to reduce the number of neuromorphic cores needed for mapping. The backward analysis using pipelining may partition an input image and the pipelining technique is performed on each partitioned image at each instance.

In one exemplary embodiment, three exemplary different options of mapping (e.g. using block, toeplitz and hybrid) each neural network layer onto a neuromorphic core is considered depending on a current convolutional layer and the next convolutional layer in the deep learning architecture. Thus, the connectivity pattern of an interconnection at a crossbar array of synapses may be block, toeplitz, or a combination of block and toeplitz. A hybrid of block and Toeplitz may itself comprise different hybrids. e.g. compare FIGS. 7D and 7E.

In one exemplary embodiment, there may be provided a backward analysis using pipelining technique to map deep neural network architectures onto multiple neuromorphic cores with a crossbar array(s) of synapses interconnecting a plurality of electronic neurons. A novel split pipelining technique in which both backward pipelining and e.g. forward pipelining has been proposed to further reduce a utilization of neuromorphic cores. Compare e.g. the B/BAPM and/or the B/FAPM processes. The different options of mapping the synaptic weights within a single neuromorphic core efficiently with respect to different convolutional layers may also be utilised.

In the present disclosure, there may be provided a method of mapping a convolutional neural network to a neuromorphic core comprising interconnected arrays of input axons and output neurons for processing data e.g. an image, the method may comprise selecting one layer of the convolutional neural network to start pipeline processing, identifying iteratively a number of activations of one layer of the convolutional neural network to generate a single activation in next layer (the selected one layer) of the convolutional neural network; effectively partitioning the image for processing using a portion or a subset of interconnected arrays of axons and neurons.

In the present disclosure, there may be provided a method of mapping a convolutional neural network to a neuromorphic core comprising interconnected arrays of input axons and output neurons for processing data e.g. an image, the method further comprising selecting an intermediate layer to start the pipeline processing in one direction, determining a number of neuron activations based on a number of layers, a number of shifts, determining the number of cores needed to map each layer with the determined number of neurons, and wherein the interconnected arrays of axons and neurons may form a synaptic crossbar of axons and neurons; whereby each interconnection is a synapse that may perform multiplication and storage, while a neuron may generates spikes when integration of weighted inputs exceeds a threshold.

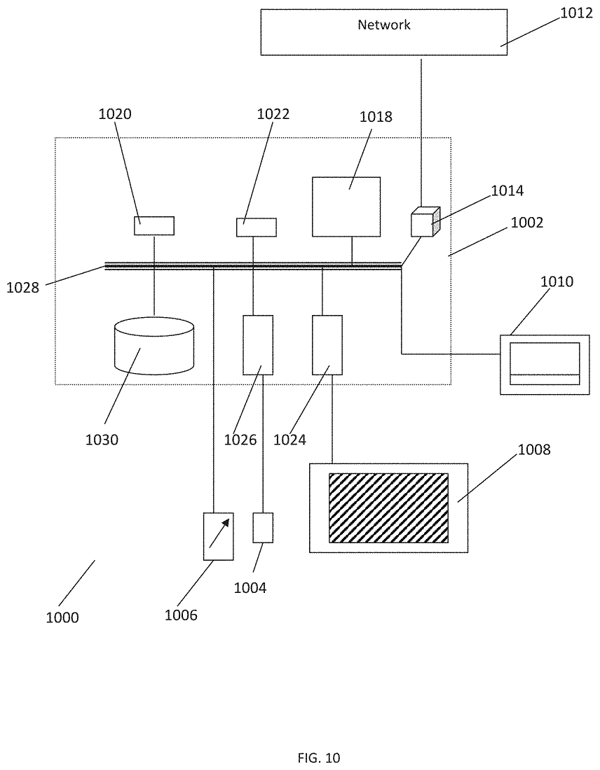

Different exemplary embodiments can be implemented in the context of data structure, program modules, program and computer instructions executed in a computer implemented environment. A general purpose computing environment is briefly disclosed herein. One or more exemplary embodiments may be embodied in one or more computer systems, such as is schematically illustrated in FIG. 10.

One or more exemplary embodiments may be implemented as software, such as a computer program being executed within a computer system 1000, and instructing the computer system 1000 to conduct a method of an exemplary embodiment.

The computer system 1000 comprises a computer unit 1002, input modules such as a keyboard 1004 and a pointing device 1006 and a plurality of output devices such as a display 1008, and printer 1010. A user can interact with the computer unit 1002 using the above devices. The pointing device can be implemented with a mouse, track ball, pen device or any similar device. One or more other input devices (not shown) such as a joystick, game pad, satellite dish, scanner, touch sensitive screen or the like can also be connected to the computer unit 1002. The display 1008 may include a cathode ray tube (CRT), liquid crystal display (LCD), field emission display (FED), plasma display or any other device that produces an image that is viewable by the user.

The computer unit 1002 can be connected to a computer network 1012 via a suitable transceiver device 1014, to enable access to e.g. the Internet or other network systems such as Local Area Network (LAN) or Wide Area Network (WAN) or a personal network. The network 1012 can comprise a server, a router, a network personal computer, a peer device or other common network node, a wireless telephone or wireless personal digital assistant. Networking environments may be found in offices, enterprise-wide computer networks and home computer systems etc. The transceiver device 1014 can be a modem/router unit located within or external to the computer unit 1002, and may be any type of modem/router such as a cable modem or a satellite modem.

It will be appreciated that network connections shown are exemplary and other ways of establishing a communications link between computers can be used. The existence of any of various protocols, such as TCP/IP, Frame Relay. Ethernet. FTP, HTTP and the like, is presumed, and the computer unit 1002 can be operated in a client-server configuration to permit a user to retrieve web pages from a web-based server. Furthermore, any of various web browsers can be used to display and manipulate data on web pages.

The computer unit 1002 in the example comprises a processor 1018, a Random Access Memory (RAM) 1020 and a Read Only Memory (ROM) 1022. The ROM 1022 can be a system memory storing basic input/output system (BIOS) information. The RAM 1020 can store one or more program modules such as operating systems, application programs and program data.

The computer unit 1002 further comprises a number of Input/Output (I/O) interface units, for example I/O interface unit 1024 to the display 1008, and I/O interface unit 1026 to the keyboard 1004. The components of the computer unit 1002 typically communicate and interface/couple connectedly via an interconnected system bus 1028 and in a manner known to the person skilled in the relevant art. The bus 1028 can be any of several types of bus structures including a memory bus or memory controller, a peripheral bus, and a local bus using any of a variety of bus architectures.

It will be appreciated that other devices can also be connected to the system bus 1028. For example, a universal serial bus (USB) interface can be used for coupling a video or digital camera to the system bus 1028. An IEEE 1394 interface may be used to couple additional devices to the computer unit 1002. Other manufacturer interfaces are also possible such as FireWire developed by Apple Computer and i.Link developed by Sony. Coupling of devices to the system bus 1028 can also be via a parallel port, a game port, a PCI board or any other interface used to couple an input device to a computer. It will also be appreciated that, while the components are not shown in the figure, sound/audio can be recorded and reproduced with a microphone and a speaker. A sound card may be used to couple a microphone and a speaker to the system bus 1028. It will be appreciated that several peripheral devices can be coupled to the system bus 1028 via alternative interfaces simultaneously.

An application program can be supplied to the user of the computer system 1000 being encoded/stored on a data storage medium such as a CD-ROM or flash memory carrier. The application program can be read using a corresponding data storage medium drive of a data storage device 1030. The data storage medium is not limited to being portable and can include instances of being embedded in the computer unit 1002. The data storage device 1030 can comprise a hard disk interface unit and/or a removable memory interface unit (both not shown in detail) respectively coupling a hard disk drive and/or a removable memory drive to the system bus 1028. This can enable reading/writing of data. Examples of removable memory drives include magnetic disk drives and optical disk drives. The drives and their associated computer-readable media, such as a floppy disk provide nonvolatile storage of computer readable instructions, data structures, program modules and other data for the computer unit 1002. It will be appreciated that the computer unit 1002 may include several of such drives. Furthermore, the computer unit 1002 may include drives for interfacing with other types of computer readable media.

The application program is read and controlled in its execution by the processor 1018. Intermediate storage of program data may be accomplished using RAM 1020. The method(s) of the exemplary embodiments can be implemented as computer readable instructions, computer executable components, or software modules. One or more software modules may alternatively be used. These can include an executable program, a data link library, a configuration file, a database, a graphical image, a binary data file, a text data file, an object file, a source code file, or the like. When one or more computer processors execute one or more of the software modules, the software modules interact to cause one or more computer systems to perform according to the teachings herein.

The operation of the computer unit 1002 can be controlled by a variety of different program modules. Examples of program modules are routines, programs, objects, components, data structures, libraries, etc. that perform particular tasks or implement particular abstract data types. The exemplary embodiments may also be practiced with other computer system configurations, including handheld devices, multiprocessor systems, microprocessor-based or programmable consumer electronics, network PCs, minicomputers, mainframe computers, personal digital assistants, mobile telephones and the like. Furthermore, the exemplary embodiments may also be practiced in distributed computing environments where tasks are performed by remote processing devices that are linked through a wireless or wired communications network. In a distributed computing environment, program modules may be located in both local and remote memory storage devices.

The terms “coupled” or “connected” as used in this description are intended to cover both directly connected or connected through one or more intermediate means, unless otherwise stated.

The description herein may be, in certain portions, explicitly or implicitly described as algorithms and/or functional operations that operate on data within a computer memory or an electronic circuit. These algorithmic descriptions and/or functional operations are usually used by those skilled in the information/data processing arts for efficient description. An algorithm is generally relating to a self-consistent sequence of steps leading to a desired result. The algorithmic steps can include physical manipulations of physical quantities, such as electrical, magnetic or optical signals capable of being stored, transmitted, transferred, combined, compared, and otherwise manipulated.

Further, unless specifically stated otherwise, and would ordinarily be apparent from the following, a person skilled in the art will appreciate that throughout the present specification, discussions utilizing terms such as “scanning”, “calculating”, “determining”, “replacing”, “generating”, “initializing”, “outputting”, and the like, refer to action and processes of an instructing processor/computer system, or similar electronic circuit/device/component, that manipulates/processes and transforms data represented as physical quantities within the described system into other data similarly represented as physical quantities within the system or other information storage, transmission or display devices etc.

The description also discloses relevant device/apparatus for performing the steps of the described methods. Such apparatus may be specifically constructed for the purposes of the methods, or may comprise a general purpose computer/processor or other device selectively activated or reconfigured by a computer program stored in a storage member. The algorithms and displays described herein are not inherently related to any particular computer or other apparatus. It is understood that general purpose devices/machines may be used in accordance with the teachings herein. Alternatively, the construction of a specialized device/apparatus to perform the method steps may be desired.

In addition, it is submitted that the description also implicitly covers a computer program, in that it would be clear that the steps of the methods described herein may be put into effect by computer code. It will be appreciated that a large variety of programming languages and coding can be used to implement the teachings of the description herein. Moreover, the computer program if applicable is not limited to any particular control flow and can use different control flows without departing from the scope of the invention.

Furthermore, one or more of the steps of the computer program if applicable may be performed in parallel and/or sequentially. Such a computer program if applicable may be stored on any computer readable medium. The computer readable medium may include storage devices such as magnetic or optical disks, memory chips, or other storage devices suitable for interfacing with a suitable reader/general purpose computer. In such instances, the computer readable storage medium is non-transitory. Such storage medium also covers all computer-readable media e.g. medium that stores data only for short periods of time and/or only in the presence of power, such as register memory, processor cache and Random Access Memory (RAM) and the like. The computer readable medium may even include a wired medium such as exemplified in the Internet system, or wireless medium such as exemplified in bluetooth technology. The computer program when loaded and executed on a suitable reader effectively results in an apparatus that can implement the steps of the described methods.

The exemplary embodiments may also be implemented as hardware modules. A module is a functional hardware unit designed for use with other components or modules. For example, a module may be implemented using digital or discrete electronic components, or it can form a portion of an entire electronic circuit such as an Application Specific Integrated Circuit (ASIC). A person skilled in the art will understand that the exemplary embodiments can also be implemented as a combination of hardware and software modules.

Additionally, when describing some embodiments, the disclosure may have disclosed a method and/or process as a particular sequence of steps. However, unless otherwise required, it will be appreciated the method or process should not be limited to the particular sequence of steps disclosed. Other sequences of steps may be possible. The particular order of the steps disclosed herein should not be construed as undue limitations. Unless otherwise required, a method and/or process disclosed herein should not be limited to the steps being carried out in the order written. The sequence of steps may be varied and still remain within the scope of the disclosure.

Further, in the description herein, the word “substantially” whenever used is understood to include, but not restricted to, “entirely” or “completely” and the like. In addition, terms such as “comprising”, “comprise”, and the like whenever used, are intended to be non-restricting descriptive language in that they broadly include elements/components recited after such terms, in addition to other components not explicitly recited. Further, terms such as “about”, “approximately” and the like whenever used, typically means a reasonable variation, for example a variation of +/−5% of the disclosed value, or a variance of 4% of the disclosed value, or a variance of 3% of the disclosed value, a variance of 2% of the disclosed value or a variance of 1% of the disclosed value.

Furthermore, in the description herein, certain values may be disclosed in a range. The values showing the end points of a range are intended to illustrate a preferred range. Whenever a range has been described, it is intended that the range covers and teaches all possible sub-ranges as well as individual numerical values within that range. That is, the end points of a range should not be interpreted as inflexible limitations. For example, a description of a range of 1% to 5% is intended to have specifically disclosed sub-ranges 1% to 2%, 1% to 3%, 1% to 4%, 2% to 3% etc., as well as individually, values within that range such as 1%, 2%, 3%, 4% and 5%. The intention of the above specific disclosure is applicable to any depth/breadth of a range.

In the described exemplary embodiments, the mapping is performed onto a computing core such as a neuromorphic core. It will be appreciated that the exemplary embodiments are not limited as such and may be applicable to any form of cores that may be later developed.

In the described exemplary embodiments, the selected intermediate layer may be denoted as layer N or layer N₀. It will be appreciated that such notations may be interchangeable.

Further, backward analysis from a selected intermediate layer may be described as towards an input layer of a neural network. It will be appreciated that the term “backwards” broadly describes the direction of analysis and may not be limited to the analysis reaching the input (or first) layer. In some exemplary embodiments, the analysis may indeed reach the input (or first) layer. Similarly, for a backward analysis towards the selected intermediate layer, it will be appreciated that the term “backwards” broadly describes the direction of analysis and may not be limited to the analysis beginning from an end (or last) layer. The backward analysis towards the selected intermediate layer may be from another layer that is further from the input layer as compared to (or than) the selected intermediate layer. In such a case, the backward analysis is from the another layer backwards towards the selected layer and the input layer. In some exemplary embodiments, the analysis may indeed begin from an end (or last) layer.

Further, forward analysis from an intermediate layer may be described as towards an output layer of a neural network. It will be appreciated that the term “forward” broadly describes the direction of analysis away from the selected intermediate layer and the input layer, and may not be limited to the analysis reaching the output layer. In some exemplary embodiments, the analysis may indeed reach the output (or an end or last) layer.

In the described exemplary embodiments, it will be appreciated that the exemplary embodiments may broadly encompass performance of the backward analysis from one intermediate layer of a neural network to another intermediate layer of the neural network. For example, for a large neural network, different combinations of the B/BAPM and/or B/FAPM may be performed such that different sections of the large neural network may be mapped respectively to a plurality of computing cores. Thus, some sections, and therefore some cores, may comprise one intermediate layer to another intermediate layer of the neural network.

In the described exemplary embodiments, the terms “backward” and “forward” generally describe the direction of calculation or determination from a selected layer. The terms “backward pipeline” or “backward pipelining” or “forward pipeline” or “forward pipelining” indicate a more specific form of calculation or determination from a selected layer, i.e. in relation to a specific node or neuron of the selected layer. In many circumstances, the broader terms “backward” and “forward” may be used interchangeably with “backward pipeline” or “backward pipelining” and “forward pipeline” or “forward pipelining” respectively.

In the described exemplary embodiments, for the mapping, three exemplary methods/processes/algorithms have been proposed. However, it will be appreciated that the exemplary embodiments are not limited as such. That is, other forms of methods/processes/algorithms may also be used for the mapping onto a computing core.

In the described exemplary embodiments, input data is provided to an input layer. The input data may be an input image or input image data. It will be appreciated that input data is not limited as such and may also refer to other forms of input data suitable for use with neural networks.

It will be appreciated by a person skilled in the art that other variations and/or modifications may be made to the specific embodiments without departing from the scope of the invention as broadly described. The present embodiments are, therefore, to be considered in all respects to be illustrative and not restrictive.

1. A system for mapping a neural network architecture onto a computing core, the system comprising,
a neural network module configured to provide a neural network;
a data input module coupled to the neural network module, the data input module configured to provide input data to the neural network;
a layer selector module coupled to the neural network module, the layer selector module configured to select a layer of the neural network;
a pipeline module coupled to the layer selection module, the pipeline module configured to perform at least one backward pipelining analysis from the selected layer of the layer selector module, the pipeline module being arranged to perform the at least one backward pipelining analysis towards an input layer of the neural network;
a mapper module coupled to the pipeline module, the mapper module being arranged to receive activation information from the pipeline module, the activation information based on the at least one backward pipelining analysis; and
wherein the mapper module is further arranged to map at least the selected layer of the neural network using the activation information to a computing core.

2. The system as claimed in claim 1, wherein the layer selection module is configured to select the layer of the neural network between the input layer and an output layer of the neural network.

3. The system as claimed in claim 1, wherein the pipeline module is further configured to perform at least one forward pipelining analysis from the selected layer of the layer selector module, the pipeline module being arranged to perform the at least one forward pipelining analysis from the selected layer away from the input layer.

4. The system as claimed in claim 1, wherein the pipeline module is further configured to perform at least another backward pipelining analysis from another layer further from the input layer than the selected layer, the at least another backward pipelining analysis being from the another layer towards the selected layer and the input layer.

5. The system as claimed in claim 1, wherein the activation information comprises an identification of and a number of activations needed in each layer of the neural network for the generation of activations in an adjacent layer of the each layer, the each layer being analysed in the at least one backward pipelining analysis.

6. The system as claimed in claim 1, wherein the mapper module is further arranged to perform the mapping to the computing core based on a crossbar array of synapses, the crossbar array providing an interconnected relationship between axons and neurons with each synapse arranged for at least one mathematical operation.

7. The system as claimed in claim 6, wherein the mapper module is further arranged to perform the mapping to the computing core with the crossbar array of synapses, the mapping being based on a matrix method.

8. The system as claimed in claim 7, wherein the matrix method is selected from a group consisting of a block matrix, a Toeplitz matrix and a hybrid matrix of a block matrix and Toeplitz matrix.

9. The system as claimed in claim 1, further comprising a first storage module, the first storage module being configured to store the activation information relating to the selected layer, output information relating to the selected layer or both.

10. A method of mapping a neural network architecture onto a computing core, the method comprising,
providing a neural network;
providing input data to the neural network;
selecting a layer of the neural network;
performing at least one backward pipelining analysis from the selected layer towards an input layer of the neural network;
determining activation information based on the at least one backward pipelining analysis; and
mapping at least the selected layer of the neural network using the activation information to a computing core.

11. The method as claimed in claim 10, wherein the step of selecting a layer of the neural network comprises selecting the layer between the input layer and an output layer of the neural network.

12. The method as claimed in claim 10, further comprising performing at least one forward pipelining analysis from the selected layer away from the input layer.

13. The method as claimed in claim 10, further comprising performing at least another backward pipelining analysis from another layer further from the input layer than the selected layer, the at least another backward pipelining analysis being from the another layer towards the selected layer and the input layer.

14. The method as claimed in claim 10, wherein the step of determining activation information based on the at least one backward pipelining analysis comprises identifying activations and determining a number of activations needed in each layer of the neural network for the generation of activations in an adjacent layer of the each layer, the each layer being analysed in the at least one backward pipelining analysis.

15. The method as claimed in claim 10, wherein the step of mapping at least the selected layer of the neural network with the activation information to a computing core comprises performing the mapping based on a crossbar array of synapses, the crossbar array providing an interconnected relationship between axons and neurons with each synapse arranged for at least one mathematical operation.

16. The method as claimed in claim 15, further comprising performing the mapping to the computing core based on a matrix method.

17. The method as claimed in claim 16, further comprising selecting the matrix method from a group consisting of a block matrix, a Toeplitz matrix and a hybrid matrix of a block matrix and Toeplitz matrix.

18. The method as claimed in claim 10, further comprising storing the activation information relating to the selected layer, or storing output information relating to the selected layer or storing both the activation information relating to the selected layer and output information relating to the selected layer.
